(19) United States
(12) Patent Application Publication
(10) Pub. No.: US 2026/0239584 A1
(43) Pub. Date: Aug. 13, 2026

(54) INVERTER DEVICE FOR AN ELECTRIC AXLE OF A MOTOR VEHICLE, AND ELECTRIC AXLE

(71) Applicant: Schaeffler Technologies AG & Co. KG, Herzogenaurach (DE)

(72) Inventors: Julian Körner, Karlsruhe (DE); Nicolai Gramann, Renchen (DE); Mihai Cretu, Kappelrodeck (DE); Thorsten Rittgerott, Offenburg (DE); Eduard Enderle, Gengenbach (DE); Sebastian Jackstädt, Hilden (DE)

(73) Assignee: Schaeffler Technologies AG & Co. KG, Herzogenaurach (DE)

(21) Appl. No.: 19/155,245

(22) PCT Filed: Jan. 29, 2024
(86) PCT No.: PCT/DE2024/100076

§ 371 Date: Aug. 9, 2025

(30) Foreign Application Priority Data
Feb. 9, 2023 (DE) 10 2023 103 136.8

(51) Int. Cl. H05K 7/20; B60L 15/00; H02M 1/44; H02M 7/00

(52) U.S. Cl. CPC H05K 7/20927; B60L 15/007; H02M 1/44; H02M 7/003; H05K 7/20263; H05K 7/20509; B60L 2210/40

(57) ABSTRACT

An inverter device for an electric axle of a motor vehicle is provided. The inverter device includes two separate electric machines to be driven via the inverter device. The inverter device includes two separate inverters to which a common control device and a common capacitor and a common EMC filter are assigned. The inverters, the control device, the capacitor and the EMC filter are accommodated in a common housing.

### CROSS-REFERENCE TO RELATED APPLICATIONS

This application is the United States National Phase of International Application PCT/DE2024/100076, filed Jan. 29, 2024, which claims priority to German Application 10 2023 103 136.8, filed Feb. 9, 2023. The disclosures of the above applications are incorporated herein by reference.

### TECHNICAL FIELD

The disclosure relates to an inverter device for an electric axle of a motor vehicle, including two separate electric machines to be operated via the inverter device.

### BACKGROUND

Electrically driven motor vehicles have at least one electric axle in which two separate electric machines are integrated, each driving one wheel. Each electric machine is assigned an inverter device, each of which has at least one inverter, i.e., a corresponding semiconductor power module, a control device, a capacitor, and an EMC filter. The corresponding assemblies are arranged in a housing, where a corresponding cooling device is often also provided on the housing side. This design can lead to problems integrating the inverter devices into the axle.

### SUMMARY

The disclosure provides an inverter device that is improved in comparison.

An inverter device of the type mentioned at the outset includes two separate inverters to which a common control device and a common capacitor, and a common EMC filter are assigned. The inverters, the control device, the capacitor, and the EMC filter are accommodated in a common housing.

In some examples, a double inverter has two separate inverters, i.e., two separate semiconductor power modules, where an electric machine is operated via one power module in each case. However, a common control device is assigned to both inverters, which means that one control device controls both inverters, i.e., both power modules, accordingly. Likewise, only one common capacitor is assigned, which is connected to both inverters, for which corresponding busbars are used. Although the capacitor is somewhat larger than in the previously known design with separate inverter devices, only one common component is required here too. The same applies to the EMC filter, which is also assigned to both inverters, so only one component is required here too.

All components or assemblies are housed in a common housing, which is ultimately only slightly larger than in previously known designs with separate inverter devices. Ultimately, the housing only has to accommodate an additional inverter and the slightly larger capacitor and, if necessary, the slightly larger EMC filter. However, this does not lead to a significant increase in housing size, such that the overall result is a very compact inverter device that requires far less installation space than two separate inverter devices, each assigned to an electric machine. On the one hand, this allows installation space to be saved, or the integration of an electric axle is also possible with a correspondingly small installation space. On the other hand, assembly is also simplified as only one common inverter device has to be integrated on the axle side. This integration takes place in the center of the axle between the two electric machines, which are connected almost directly to the centrally arranged inverter device on both sides, as seen in the direction of the axle.

In some implementations, only one common cooling device is provided, via which at least the two inverters are cooled together. Whereas in the prior art with separate inverter devices in an electric axle, each inverter device has a separate cooling device in order to cool at least the inverters, i.e., the semiconductor power modules, which heat up considerably during operation, according to the disclosure only one common cooling device is provided in the common housing, via which both inverters are cooled. This also results in considerable simplification, as this cooling device is also much easier to integrate into a corresponding cooling circuit than two separate cooling devices in the prior art.

In some examples, the cooling device has a first plate-shaped cooling element to which the two inverters, and possibly the control device, are coupled in a thermally conductive manner. This plate-shaped cooling element makes it easy to achieve a large-area heat-conducting or thermal coupling of the two inverters. These can, for example, be arranged directly on both sides of the plate-shaped cooling element or fastened to it, resulting in a kind of sandwich arrangement with the two inverters and the plate-shaped cooling element arranged between them. On the one hand, this enables an optimum heat-conducting coupling to be achieved, and on the other hand, both inverters can be cooled synchronously in a simple manner, resulting in a very compact arrangement.

In some examples, the cooling element is coupled to the capacitor in a thermally conductive manner. The capacitor also heats up during operation. If the capacitor is now arranged closely adjacent to the first cooling device in a way that optimizes the installation space and is coupled to it in a thermally conductive manner, the heat generated on the capacitor side can also be absorbed and dissipated via the first cooling device.

Furthermore, in some implementations, the cooling device is additionally provided with a second plate-shaped cooling element, to which at least the capacitor, and possibly also the EMC filter, is coupled in a thermally conductive manner. This second plate-shaped cooling element can be used to cool the capacitor directly and, if necessary, also the EMC filter. Once again, a plate-shaped cooling element is used, to which the capacitor is fastened in a heat-conducting manner, so that the best possible heat transfer from the capacitor to the cooling element is also possible here, similar to the inverters.

A coolant flows through the first plate-shaped cooling element, so it is integrated into a corresponding cooling circuit. If a second plate-shaped cooling element is used for additional capacitor cooling, a cooling fluid should also flow through it. In some examples, both cooling elements are integrated into a common coolant circuit so that the coolant first circulates through one cooling element and then through the other and dissipates the heat.

The two cooling elements may be connected directly downstream of each other, i.e., there is a fluid-conducting connection between the first and second cooling element. This is ultimately possible without any problems, as both are accommodated in the common housing as described and are also arranged close to each other to achieve the greatest possible compactness.

In some implementations, the first cooling element itself, to which the two inverters are coupled, is mechanically fastened in the housing and at the same time serves as a support for the two inverters arranged on both sides thereof. The cooling element therefore has a dual function, on the one hand its original cooling function, but on the other hand also that of a support, i.e., a holding element for the two inverters, which are fastened to it with suitable fastening means. A contact interface that is as flat as possible is used for the best possible heat transfer.

The EMC filter itself may be shielded in a separate part of the housing, i.e., in a separate EMC chamber, and can be separated from the other components and shielded accordingly.

In addition to the inverter device itself, an electric axle for a motor vehicle is also provided and includes two separate electric machines and an inverter device of the type described above, arranged between them, for example.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a basic illustration of an exemplary electric axle having an inverter device.

FIG. 2 shows a basic illustration of an exemplary inverter device.

Like reference symbols in the various drawings indicate like elements.

### DETAILED DESCRIPTION

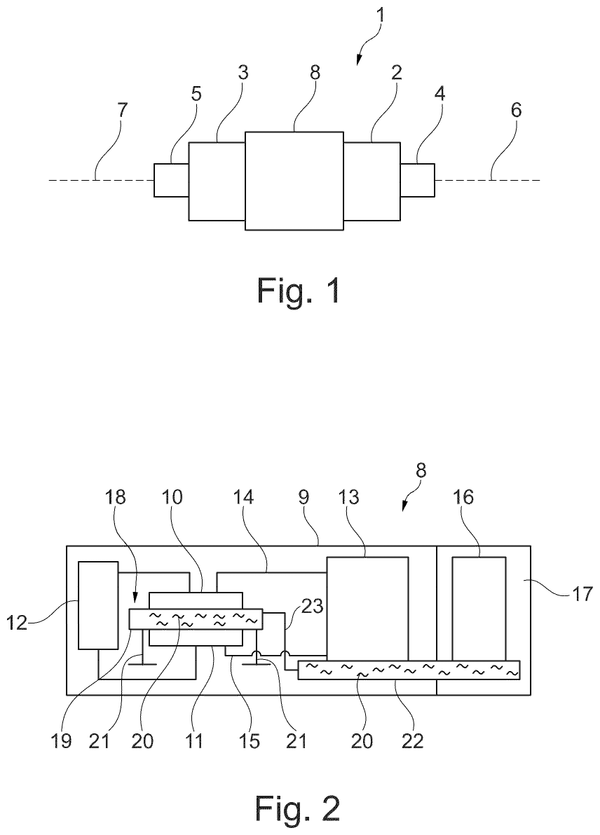

FIG. 1 shows a partial view of an exemplary electric axle 1 as a basic illustration. The electric axle includes two separate electric machines 2, 3, each of which is connected downstream of a transmission 4, 5, which operates on a corresponding output axle 6, 7, which in turn runs to corresponding wheels to be driven. An inverter device 8 is arranged between the two electric machines 2, 3, which is described in more detail below with reference to FIG. 2. The common inverter device 8 operates both electric machines 2, 3, i.e., controls them or supplies them with power or passes on any recuperated power.

The common inverter device 8 is shown in more detail in the form of a basic illustration in FIG. 2. The common inverter device 8 includes a housing 9 in which two inverters 10, 11 are accommodated. An inverter 10, 11 is assigned to each electric machine 2, 3.

Both inverters 10, 11 are assigned a common control device 12, via which they are controlled separately.

Furthermore, a common capacitor 13 is provided in the housing 9, which is electrically connected to both inverters 10, 11, for which purpose suitable busbars 14, 15 are provided, which can, for example, be designed to lie on top of each other, i.e., as a laminate. The electrical connection can be made, for example, by laser welding and similar methods. The capacitor is dimensioned accordingly, as it is assigned to both inverters 10, 11.

An EMC filter 16 is also provided, which is housed in a separate housing compartment 17 and shielded accordingly.

During operation of the inverter device 8, heat is generated which must be dissipated. This applies to the two inverters 10, 11, which are designed as semiconductor power modules and heat up accordingly depending on the load. A common cooling device 18 is provided for this purpose. The common cooling device includes a plate-shaped cooling element 19 through which a cooling fluid 20 flows, i.e., the cooling element 19 is integrated in a cooling circuit. The cooling element 19, which is fastened in the housing via suitable fastening means 21 (i.e., a fastener), also serves as a support for the two inverters 10, 11, which are arranged on both sides of the plate-shaped cooling element 19 in the best possible thermally conductive contact and fastened there. A plant with as large an area as possible may be used. This results in a kind of sandwich arrangement, having the two inverters 10, 11 and the plate-shaped cooling element 19 between them. Any heat generated is transferred from the inverters 10, 11 to the cooling element 19 and is dissipated via the circulating cooling fluid 20.

Furthermore, a second plate-shaped cooling element 22 is provided as part of the cooling device 18, on which at least the capacitor 13 is arranged in thermally conductive contact. This is because heat is also generated at the capacitor 13, which heat must then be dissipated. The cooling fluid 20 also flows through the cooling element 22, where the two cooling elements 19 and 22 are connected to each other via a connecting line 23, so that they are therefore fluidically coupled to each other and both are integrated in a common circuit. The cooling fluid therefore flows via a supply line, for example, first into the first cooling device 19 and from there via the connecting line 23 into the second cooling device 22 and from there into a discharge line back into the circuit. The supply and discharge lines are routed into the housing via corresponding housing openings and connected to the cooling elements 19, 22 in a suitable manner. This enables efficient active heat dissipation.

In some examples, FIG. 2 shows the possibility that the second cooling element 22 also extends into the second housing compartment 17, so that cooling of the EMC filter 16 is also possible, if necessary. The EMC filter 16 would therefore also be thermally coupled to the cooling element 22. However, this is not mandatory; the cooling element 22 can also be used exclusively for capacitor cooling and only be connected to the capacitor 13.

In some examples, the control device 16 is coupled to the first cooling element 18 in a thermally conductive manner, so that any heat generated at the control device 12 can also be dissipated.

In some implementations, the capacitor 13 contacts the first cooling element in a thermally conductive manner when it is arranged directly adjacent to the first cooling element, so that heat generated at the capacitor 13 can be dissipated not only via the second cooling element 22, but also via the first cooling element 19.

The housing itself can, for example, include two separate housing halves into which the corresponding components are installed, after which the two housing halves are closed in a media-tight manner to form a sealed housing 9. Of course, the housing can also be multi-part, but it is always media-tight when closed to prevent moisture from penetrating.

The described inverter device 8 is therefore a very compact component that is able to operate both electric machines 2, 3. Only two separate inverters 10, 11, one of which is assigned to each electric machine 2, 3, are to be provided as quasi duplicate components. All other components, namely the common control device 12, the common capacitor 13, and the common EMC filter 16, are only to be provided as individual components, with sufficient dimensions and design, and operate both inverters 10, 11 together. Since the components operating both electric machines are also housed in a single, common housing 9, the inverter device 8 can therefore be arranged without any problems, even where installation space is limited. This is because, as in the prior art, there are not two separate inverter devices or correspondingly dimensioned housings to be installed on the axle side, but only one common or central inverter device 8, which, as shown in FIG. 1, can be positioned centrally between the two electric machines 2, 3.

A number of implementations have been described. Nevertheless, it will be understood that various modifications may be made without departing from the spirit and scope of the disclosure. Accordingly, other implementations are within the scope of the following claims.

### REFERENCE NUMERALS

1 Electric axle
2 Electric machine
3 Electric machine
4 Transmission
5 Transmission
6 Output axle
7 Output axle
8 Inverter device
9 Housing
10 Inverter
11 Inverter
12 Control device
13 Capacitor
14 Busbar
15 Busbar
16 EMC filter
17 Housing compartment
18 Cooling device
19 Cooling element
20 Cooling fluid
21 Fastening means
22 Cooling element
23 Connection line

1. An inverter device for an electric axle of a motor vehicle, the inverter device comprising:
a first electric machine;
a second electric machine, the first and second electric machines are driven via the inverter device;
a first inverter;
a second inverters;
a common control device;
a common capacitor;
a common EMC filter, wherein the common control device, the common capacitor, and the common EMC filter are assigned to the first and second inverter; and
a common housing including the first and second inverters, the common control device, the common capacitor, and the common EMC filter.

2. The inverter device of claim 1, further comprising a common cooling device via which at least the first and the second inverters are cooled together.

3. The inverter device of claim 2, wherein the common cooling device includes a first plate-shaped cooling element, to which the first and second inverters and the common control device are coupled in a thermally conductive manner.

4. The inverter device of claim 3, wherein the first plate-shaped cooling element is coupled to the common capacitor in a thermally conductive manner.

5. The inverter device of claim 3, wherein the common cooling device has a second plate-shaped cooling element, to which at least the common capacitor, and the common EMC filter, are coupled in a thermally conductive manner.

6. The inverter device of claim 5, wherein the first and second plate-shaped cooling elements have a cooling fluid flowing through them and are integrated in a common flow circuit.

7. The inverter device of claim 6, wherein the first and second plate-shaped cooling elements are connected directly downstream of one another.

8. The inverter device of claim 3, wherein the first plate-shaped cooling element is mechanically fastened in the common housing and serves as a support for the first and second inverters arranged on both sides thereof.

9. The inverter device of claim 1, wherein the common EMC filter is shielded in a separate housing compartment.

10. An electric axle for a motor vehicle, comprising two separate electric machines and an inverter device of claim 1.
